(19) United States
(12) Patent Application Publication
(10) Pub. No.: US 2023/0329076 A1
(43) Pub. Date: Oct. 12, 2023

(54) DEPOSITION APPARATUS FOR ORGANIC LIGHT-EMITTING DIODE

(71) Applicant: LG CHEM, LTD., Seoul (KR)

(72) Inventors: Kwang Jin JEONG, Daejeon (KR); Heeyoung SHIN, Daejeon (KR); Jae Il KIM, Daejeon (KR); Jun Young LEE, Daejeon (KR)

(21) Appl. No.: 18/023,590

(22) PCT Filed: Nov. 17, 2021
(86) PCT No.: PCT/KR2021/016862

§ 371 Date: Feb. 27, 2023

(30) Foreign Application Priority Data
Nov. 18, 2020 (KR) 10-2020-0154758

(51) Int. Cl. H10K 71/00; H10K 71/16; H10K 71/70

(52) U.S. Cl. CPC H10K 71/164; H10K 71/70; H10K 71/811

(57) ABSTRACT

Provided is a deposition apparatus for an organic light emitting diode, in which maint operations with deposition material are carried out independently by including an auxiliary chamber, thereby shortening the evaluation time of a deposition material.

### CROSS-REFERENCE TO RELATED APPLICATIONS

This application is a National Stage Application of International Application No. PCT/KR2021/016862 filed on Nov. 17, 2021, which claims priority to and the benefits of Korean Patent Application No. 10-2020-0154758, filed with the Korean Intellectual Property Office on Nov. 18, 2020, the entire contents of which are incorporated herein by reference.

### TECHNICAL FIELD

The present disclosure relates to a deposition apparatus for an organic light emitting diode, and in particular, to a deposition apparatus for an organic light emitting diode shortening a time of evaluation on a deposition material by independently mainting the deposition material through an auxiliary chamber.

### BACKGROUND

An organic light emitting diode (OLED) is an active light emitting device in which an organic film is provided between two electrodes separated upward and downward, and, when a current flows through the two electrodes, electrons and holes supplied from the two electrodes bind in the organic film to generate light. Such an OLED is thin and light and has properties of high luminance, low power consumption and the like, and is used in various fields. Particularly, an OLED has received attention as a next generation display, and can also be used as an illumination device emitting white light and monochromatic light.

In manufacturing an OLED, a process of forming an organic thin film and a process of forming a conductor thin film are required, and as such thin film forming processes, an evaporation deposition is mainly used.

An organic thin film is mostly made in a manner such that a crucible holding a low molecular organic material is heated by flowing a current to a heating wire surrounding the crucible, the heat transferred to the crucible increases a temperature of the organic material in the crucible, and, as the temperature of the organic material increases, the organic material exits the crucible in a gas form and is deposited on a substrate. In such manufacturing of organic thin film using a thermal deposition method, an OLED deposition device has been used.

FIG. 1 is a cross-sectional view illustrating an existing OLED deposition device.

When referring to FIG. 1, an existing OLED deposition device has a substrate (S) positioned on the upper portion, and on the lower portion, an OLED deposition device source for heating and evaporating a raw material to deposit the raw material on the substrate (S) and a thickness measurement sensor for measuring a thickness of the thin film deposited on the substrate are provided.

The OLED deposition device source is formed with a crucible accommodating an organic material, a raw material, therein, a heater wound around the crucible to electrically heat the crucible, and a nozzle unit including a plurality of nozzles provided with a spray hole spraying the raw material evaporated from the crucible by the heat from the heater.

The existing OLED deposition device includes all deposition materials in one reaction chamber, and therefore, whenever an evaporation source is replaced, a vacuum state in the chamber is vented, a new evaporation material is placed inside the chamber, and inside the chamber is made to be in a vacuum state again to conduct a dummy process, which causes a problem in that the time of deposition and the time of evaluation take a long time.

Accordingly, there have been needs for improving a deposition apparatus for an organic light emitting diode capable of evaluating some of all deposition materials or shortening a time of deposition.

### BRIEF DESCRIPTION

### Technical Problem

The present disclosure has been made in view of the above, and the present disclosure is directed to providing a deposition apparatus for an organic light emitting diode shortening a time of evaluation on a deposition material when partially depositing the deposition material by including a plurality of auxiliary chambers that include the deposition material and capable of independently conducting maint.

### Technical Solution

A deposition apparatus for an organic light emitting diode according to one embodiment of the present disclosure includes a main chamber for depositing and evaluating a material; an auxiliary chamber connected to the main chamber and into which a deposition material to deposit is loaded; and a heater heating the deposition material loaded into the auxiliary chamber.

In one embodiment, a bellows connecting the auxiliary chamber and the heater is included.

In one embodiment, the auxiliary chamber includes a load unit loading the deposition material into a cell of the main chamber.

In one embodiment, the load unit further includes a gate valve controlling movement of the deposition material.

In one embodiment, a vacuum unit making the inside of the auxiliary chamber to be in a vacuum state is further included.

In one embodiment, the auxiliary chamber is placed under the main chamber.

In one embodiment, the auxiliary chamber includes an opening/closing unit on one side for loading and unloading the deposition material.

In one embodiment, the opening/closing unit further includes a compressor for maintaining an atmosphere inside the auxiliary chamber.

In one embodiment, the auxiliary chamber and the heater are movable.

In one embodiment, a motor compressing and decompressing the bellows is further included.

### Advantageous Effects

According to the present disclosure, an effect of shortening a time of evaluation of a deposition material is obtained when the deposition material is partially deposited by including a plurality of auxiliary chambers containing the deposition material and capable of independently conducting maint or the main process.

### DESCRIPTION OF THE DRAWINGS

FIG. 1 is a cross-sectional view illustrating an existing OLED deposition device.

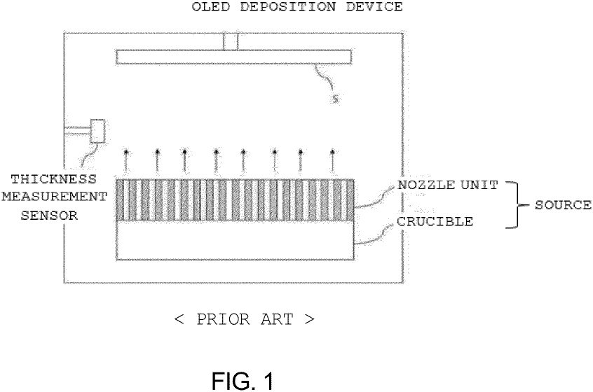

FIG. 2 is a perspective view illustrating a deposition apparatus for an organic light emitting diode according to one embodiment of the present disclosure.

FIG. 3 is an enlarged perspective view of the part A of FIG. 2.

FIG. 4A is a cross-sectional view illustrating an auxiliary chamber, a heater and a bellows before operating the heater, and FIG. 4B is a cross-sectional view illustrating the auxiliary chamber and the heater when operating the heater.

### REFERENCE NUMERALS

100: Deposition Apparatus for Organic Light Emitting Diode
10: Main Chamber
20: Auxiliary Chamber
21: Load Unit
21a: Second Level of Load Unit
21b: First Level of Load Unit
22: Gate Valve
23: Opening/Closing Unit
24: Vacuum Unit
25: Vacuum Valve
30: Heater
40: Bellows

### DETAILED DESCRIPTION

Detailed descriptions on the present disclosure are intended to fully describe the present disclosure to those skilled in the art. Throughout the specification, a description of a certain part “including” a certain constituent or being “characterized” by certain structure and shape does not exclude other constituents or exclude other structures and shapes and unless particularly stated on the contrary, and means capable of including other constituents, structures and shapes.

The present disclosure can be diversely modified and can have various embodiments, and therefore, specific embodiments will be provided and described in detail in the detailed descriptions. However, this is not intended to limit the contents of the present disclosure by the embodiments, and needs to be construed as including all modifications, equivalents and substitutes included in the ideas and the technical scope of the present disclosure.

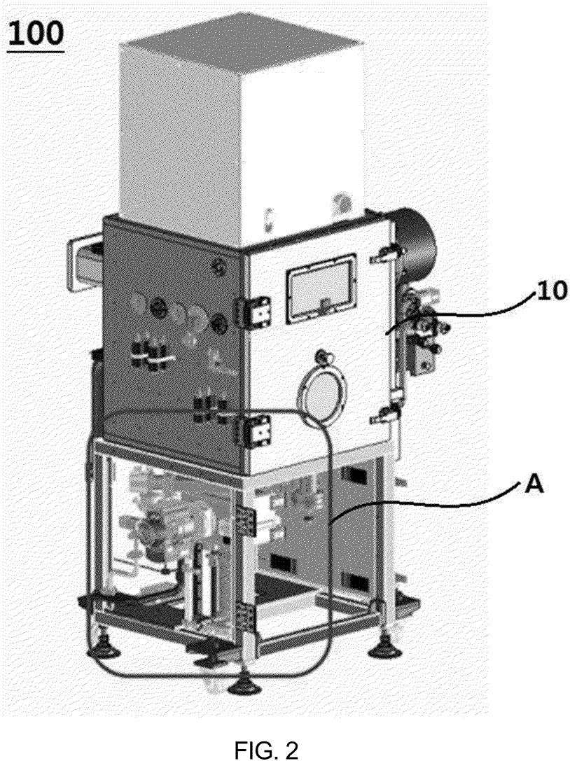

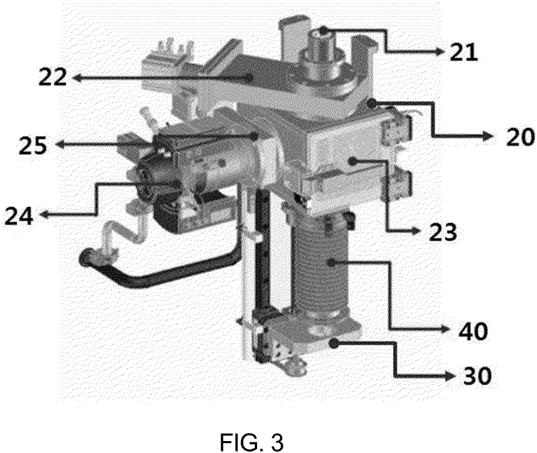

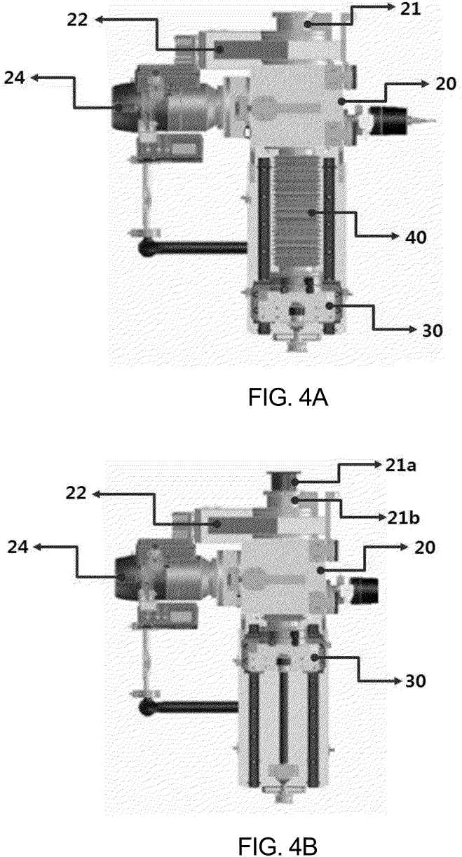

FIG. 2 is a perspective view illustrating a deposition apparatus (100) for an organic light emitting diode according to one embodiment of the present disclosure, FIG. 3 is an enlarged perspective view of the part A of FIG. 2, FIG. 4A is a cross-sectional view illustrating an auxiliary chamber (20), a heater (30) and a bellows (40) before operating the heater, and FIG. 4B is a cross-sectional view illustrating the auxiliary chamber (20) and the heater (30) when operating the heater (30).

The deposition apparatus (100) for an organic light emitting diode according to the present disclosure includes a main chamber (10) and a deposition source (A). Herein, the deposition source (A) includes an auxiliary chamber (20), a heater (30) and a bellows (40), and a deposition material is independently separated.

The main chamber (10) is configured to deposit a deposition material on a substrate, and can include a substrate support on which a substrate is placed. The main chamber (10) is preferably provided having the inside to be in a vacuum atmosphere state in order to deposit a deposition material on a substrate. Accordingly, the main chamber (10) can separately manage a vacuum atmosphere by a vacuum/atmospheric pressure control valve.

The main chamber (10) can include a plurality of cells (not shown). The cell can be connected to a load unit (21) of the auxiliary chamber (20) and load a deposition material into the main chamber (10).

The auxiliary chamber (20) is configured to be connected to the main chamber (10) and is loaded with a deposition material to be deposited. Accordingly, a container into which the deposition material is loaded can be included in the auxiliary chamber (20), and the auxiliary chamber (20) can be placed under the main chamber (10).

The auxiliary chamber (20) can independently conduct maint in order to load the deposition material into the cell of the main chamber (10). In other words, the deposition apparatus (100) for an organic light emitting diode according to the present disclosure is capable of independently mainting one deposition material by the auxiliary chamber (20). Herein, the maint is a process for conducting a dummy process, and means venting a vacuum state of the auxiliary chamber (20), then placing an evaporation material into the chamber, and creating a vacuum state inside the auxiliary chamber (20) again, and then conducting a dummy process. The dummy process means heating the auxiliary chamber (20) to remove impurities inside the auxiliary chamber (20), stabilizing the degree of vacuum inside the chamber, and vaporizing a deposition material.

Accordingly, the auxiliary chamber (20) can include a load unit (21, LTC) in order to load the deposition material into the cell of the main chamber (10). The load unit (21) is configured to connect to the auxiliary chamber (20) and the main chamber (10), and can be placed above the auxiliary chamber (20). In other words, the load unit (21) can be coupled to the cell of the main chamber (10) and load the deposition material into the main chamber (10).

In one embodiment, the load unit (21) can be provided in two levels. Herein, when a part inserted to the inside is the second level (21a) of the two levels in the load unit (21), only the first level (21b) can be provided in the load unit (21) when the main chamber (10) and the auxiliary chamber (20) are not connected. By the second level (21a) protruding and being inserted to the cell of the main chamber (10) when conducting the dummy process, the load unit (21) can connect the main chamber (10) and the auxiliary chamber (20).

The auxiliary chamber (20) can further include a gate valve (22) for controlling the deposition material moved through the load unit (21). In addition, the gate valve (22) can separate the atmosphere inside the auxiliary chamber (20) and the atmosphere inside the main chamber (10).

The gate valve (22) can be placed in the middle of the load unit (21). The gate valve (22) is preferably closed before the load unit (21) is connected to the cell of the main chamber (10).

The auxiliary chamber (20) can further include an opening/closing unit (23) on one side for loading and unloading the deposition material. In other words, the deposition material can enter and exit the auxiliary chamber (20) through the opening/closing unit (23), and the deposition material can be replaced in a container in the auxiliary chamber (20).

In addition, the opening/closing unit (23) can further include a compressor (not shown) in order to maintain the atmosphere inside the auxiliary chamber. The compressor can be placed on a surface where the auxiliary chamber (20) and the opening/closing unit (23) are brought into contact with each other.

After loading the deposition material into the container of the auxiliary chamber (20), the atmosphere formed inside the auxiliary chamber (20) needs to be the same as the atmosphere inside the main chamber (10). Accordingly, the auxiliary chamber (20) can further include a vacuum unit (24) making the inside be in a vacuum state. The deposition apparatus (100) for an organic light emitting diode according to the present disclosure further includes a vacuum valve (25) between the auxiliary chamber (20) and the vacuum unit (24) to maintain the atmosphere inside the auxiliary chamber (20) and control the vacuum unit (24).

The heater (30) is configured to heat the deposition material loaded into the auxiliary chamber (20). The heater (30) heats the auxiliary chamber (20) to a set temperature to stabilize the vacuum atmosphere inside the auxiliary chamber (20), and can vaporize the deposition material.

The heater (30) can move up/down to effectively transfer generated heat to the auxiliary chamber (20) or to stop the dummy process.

Herein, the deposition apparatus (100) for an organic light emitting diode according to the present disclosure can further include a bellows (40) connecting the auxiliary chamber (20) and the heater (30). The bellows (40) can move the heater (30) up/down through compression and tension. Heat generated in the heater (30) can be transferred to the auxiliary chamber (20) through the bellows (40).

In one embodiment, in the deposition apparatus (100) for an organic light emitting diode according to the present disclosure, the second level of the load unit (21) can protrude to be connected to the cell of the main chamber (10) when the bellows (40) is compressed and the heater (30) moves toward the auxiliary chamber (20). Herein, the load unit (21) can protrude toward the main chamber (10) by the heat generated by the heater (30) and the pressure.

In addition, the deposition apparatus (100) for an organic light emitting diode according to the present disclosure can further include a motor (not shown) in order to compress and decompress the bellows (40).

The deposition apparatus (100) for an organic light emitting diode according to the present disclosure can include one or more of the auxiliary chamber (20) and the heater (30). For example, when depositing three deposition materials, the three different deposition materials can be each loaded into three auxiliary chambers (20) to conduct the maint.

In another embodiment, the auxiliary chamber (20) and the heater (30) are movable. Herein, the deposition apparatus (100) for an organic light emitting diode can further include, under the main chamber (10), a support unit capable of supporting the auxiliary chamber (20) and the heater (30), and a rail guiding the moving path, and the auxiliary chamber (20) and the heater (30) can move along the position of the cell of the main chamber (10).

The present disclosure has been described with reference to preferred embodiments, however, those skilled in the art can understand that various modifications and changes can be made on the present disclosure within the scope not departing from the ideas and the territory of the present disclosure described in the appended claims.

1. A deposition apparatus for an organic light emitting diode, the apparatus comprising:
a main chamber for depositing and evaluating a material;
an auxiliary chamber connected to the main chamber and into which a deposition material to be deposited is loaded; and
a heater configured for heating the deposition material loaded into the auxiliary chamber.

2. The deposition apparatus of claim 1, comprising a bellows connecting the auxiliary chamber and the heater.

3. The deposition apparatus of claim 1, wherein the auxiliary chamber includes a load unit for loading the deposition material into a cell of the main chamber.

4. The deposition apparatus of claim 3, wherein the load unit further includes a gate valve controlling movement of the deposition material.

5. The deposition apparatus of claim 1, further comprising a vacuum unit for creating a vacuum state inside the auxiliary chamber.

6. The deposition apparatus of claim 1, wherein the auxiliary chamber is placed under the main chamber.

7. The deposition apparatus of claim 1, wherein the auxiliary chamber includes an opening/closing unit on one side for loading and unloading the deposition material.

8. The deposition apparatus of claim 7, wherein the opening/closing unit further includes a compressor for maintaining an atmosphere inside the auxiliary chamber.

9. The deposition apparatus of claim 1, wherein the auxiliary chamber and the heater are movable.

10. The deposition apparatus of claim 2, further comprising a motor compressing and decompressing the bellows.
